(19) United States
(12) Patent Application Publication
(10) Pub. No.: US 2025/0311509 A1
(43) Pub. Date: Oct. 2, 2025

(54) MICROLED-BASED DISPLAY DEVICES

(71) Applicant: Shoei Chemical Inc., Tokyo (JP)

(72) Inventors: HOMER ANTONIADIS, MILPITAS, CA (US); JASON HARTLOVE, MILPITAS, CA (US); ERNEST C. LEE, MILPITAS, CA (US); ALAIN BARRON, MILPITAS, CA (US)

(21) Appl. No.: 18/864,480

(22) PCT Filed: May 9, 2023
(86) PCT No.: PCT/US23/21524

§ 371 Date: Nov. 8, 2024

Related U.S. Application Data
(60) Provisional application No. 63/339,818, filed on May 9, 2022.

(51) Int. Cl. H10H 29/851; H01L 25/075; H10H 29/01

(52) U.S. Cl. CPC H10H 29/8512; H01L 25/0753; H10H 29/0361

(57) ABSTRACT

Embodiments of a display device are described. A display device includes a substrate (204) and a sub-pixel (R1, R2) configured to emit a display light having an emission spectrum with a first peak wavelength and a second peak wavelength. The sub-pixel includes a microLED (218) disposed on the substrate and a NS-based CC layer (220) disposed on the microLED. The NS-based CC layer includes QDs configured to emit a first light having the first peak wavelength. The microLED is configured to emit a second light having the second peak wavelength. A first portion of the second light is absorbed by the QDs and down-converted to the first light and a second portion of the second light is transmitted through the NS-based CC layer (220).

### BACKGROUND

### Field

The present invention relates to display devices having sub-pixels with micro-sized light emitting diodes (“microLEDs”) and color conversion (CC) layers.

### Background

Luminescent nanostructures (NSs), such as quantum dots (QDs) represent a class of phosphors that have the ability to emit light at a single spectral peak with narrow line width, creating highly saturated colors. It is possible to tune the emission wavelength based on the size of the NSs. The NSs are used to produce a NS film that can be used as a color conversion (CC) layer (also referred to as a color down-conversion layer) in display devices. The NS-based CC layers can down-convert a light from a shorter wavelength region of the visible spectrum to a light in a longer wavelength region of the visible spectrum.

Display devices can be based on microLED technology and can have red, green, and blue light-emitting microLEDs as light sources in its red, green, and blue sub-pixels. These microLED-based display devices suffer from a trade-off between achieving the desired high color brightness (e.g., brightness equal to or greater than about 50,000 nits) and the desired primary emission peak wavelength corresponding to the desired color point and/or color gamut on an RGB color space (e.g., the 1931 CIE color space) for the light emitting from the red, green, and/or blue sub-pixels. For example, GaN-based microLEDs used in the red sub-pixels emit red light in the wavelength region of about 620 nm to about 630 nm, but for a low color brightness equal to or less than about 5,000 nits and a low current density equal to or less than about 2 A/cm². The GaN-based microLEDs cannot emit red light, as desired, with a high color brightness equal to or greater than about 50,000 nits and at a high current density equal to or greater than about 4 A/cm². Rather, the GaN-based microLEDs emit light in the wavelength region of about 580 nm to about 600 nm, which corresponds to an orange light and an orange color point on the 1931 CIE color space, thus degrading the image quality of the display device.

One of the parameters used to define the light emitted from the display devices is the chromaticity (x, y) coordinates of the 1931 CIE chromaticity diagram shown in FIG. 1. The 1931 CIE chromaticity diagram (also referred to as “the 1931 CIE color space”) is a graphical representation of all colors perceived by the human eye. The horseshoe-shaped spectrum locus 100 is a set of points representing the chromaticity (x, y) coordinates of the spectrum (monochromatic) colors, plotted according to their wavelengths. The chromaticity (x, y) coordinates for any naturally occurring color are located within the bounds of the spectrum locus 100.

The color gamut boundaries of various display device technologies or specifications can be drawn within the 1931 CIE chromaticity diagram by connecting the chromaticity (x, y) coordinates of the three display color primaries of the display devices. The color gamut defines the limits of the producible or defined colors for the display device technologies or specifications. FIG. 1 illustrates the color gamut for the DCI Specification as a triangle 102 with vertices for each of the primary display colors of red, green and blue (RGB). The chromaticity (x, y) coordinates for the vertices of triangle 102 are (0.680, 0.320), (0.265, 0.690), and (0.150, 0.060), for red, green, and blue, respectively.

### SUMMARY

The present disclosure provides example microLED-based display devices that minimize or eliminate existing trade-offs between achieving the desired color brightness and the desired color point and/or color gamut for the light emitting from the red sub-pixels of the microLED-based display devices. The present disclosure also provides example, inexpensive methods for fabricating such improved devices.

In some embodiments, a microLED-based display device can include red, green, and blue sub-pixels. Each of the red, green, and blue sub-pixels can include a microLED. In some embodiments, the blue sub-pixel can include a microLED that emits a blue light having a primary emission peak wavelength (PWL) in a wavelength range of about 435 nm to about 495 nm of the EM spectrum. In some embodiments, the green sub-pixel can include a microLED that emits a green light having a primary emission PWL in a wavelength range of about 495 nm to about 570 nm of the EM spectrum. In some embodiments, the red sub-pixel can include a microLED (e.g., GaN-based microLED) that emits a yellow, an orange, or an amber light having a primary emission PWL in a wavelength range of about 550 nm to about 610 nm with a high color brightness (e.g., greater than about 25,000 nits, greater than 50,000 nits) at a current density equal to or higher than about 4 A/cm². In some embodiments, the red sub-pixel can further include a nanostructure-based (NS-based) color conversion (CC) layer disposed on the red sub-pixel microLED. The NS-based CC layer can include luminescent nanostructures having a primary emission PWL in a wavelength range of about 620 nm to about 750 nm, which can correspond to a red light.

In some embodiments, a first portion of the light from the red sub-pixel microLED can be absorbed by the luminescent nanostructures of the NS-based CC layer and re-emitted as a light with the primary emission PWL of the luminescent nanostructures. In some embodiments, a second portion of the light from the red sub-pixel microLED can be allowed to transmit through the NS-based CC layer. In some embodiments, the NS-based CC layer can be formed with an optical density of about 0.1 to about 3.0 to allow about 70% to about 1% transmission, respectively, of the microLED light at primary emission PWL through the NS-based CC layer. As a result, the light transmitted from the red sub-pixel can have a dual PWL emission spectrum.

In some embodiments, the dual PWL emission spectrum can include a first emission PWL corresponding to the primary emission PWL (e.g., about 620 nm to about 750 nm) of the luminescent nanostructures and a second emission PWL corresponding to the primary emission PWL (e.g., about 550 nm to about 610 nm) of the transmitted microLED light. In some embodiments, the dual PWL emission spectrum can correspond to a single color point (also referred to as a “blended color point”) on the 1931 CIE chromaticity diagram shown in FIG. 1. In some embodiments, the blended color point can have chromaticity (x, y) coordinates along a line between chromaticity (x, y) coordinates of about (0.5, 0.5) and chromaticity (x, y) coordinates of about (0.7, 0.3) of the 1931 CIE chromaticity diagram. In some embodiments, the dual PWL emission spectrum can include a first emission PWL at about 640 nm and a second emission PWL at about 595 nm. This dual PWL emission spectrum can correspond to a blended color point with chromaticity (x, y) coordinates of about (0.680, 0.320), which is a red color point on the 1931 CIE color space as perceived by the human eye.

Thus, with the use of the NS-based CC layer having red light-emitting luminescent nanostructures on the orange light-emitting microLEDs having an external quantum efficiency greater than about 2% in the red sub-pixels, red light emission with high red color brightness (e.g., brightness greater than about 25,000 nits, or brightness greater than about 50,000 nits) can be achieved from the red sub-pixels of the microLED-based display device.

According to some embodiments, a display device includes a substrate and a sub-pixel configured to emit a display light having an emission spectrum with a first peak wavelength and a second peak wavelength. The sub-pixel includes a microLED disposed on the substrate and a NS-based CC layer disposed on the microLED. The NS-based CC layer includes QDs configured to emit a first light having the first peak wavelength. The microLED is configured to emit a second light having the second peak wavelength. A first portion of the second light is absorbed by the QDs and down-converted to the first light and a second portion of the second light is transmitted through the NS-based CC layer.

According to some embodiments, the first peak wavelength is in a wavelength range of about 620 nm to about 750 nm.

According to some embodiments, the second peak wavelength is in a wavelength range of about 550 nm to about 610 nm.

According to some embodiments, the first and second peak wavelengths are in different and adjacent wavelength regions of an electromagnetic (EM) spectrum.

According to some embodiments, the first peak wavelength is in a red wavelength region of an electromagnetic (EM) spectrum and the second peak wavelength is in an orange or a yellow wavelength region of the EM spectrum.

According to some embodiments, an intensity of the first peak wavelength is greater than an intensity of the second peak wavelength.

According to some embodiments, a peak intensity ratio of the first peak wavelength to the second peak wavelength ranging from about 0 to about 40 corresponds to an optical transmission of the microLED ranging from about 100% to about 1% at the second peak wavelength.

According to some embodiments, the emission spectrum corresponds to a single color point having a first chromaticity (x, y) coordinates on an RGB color space.

According to some embodiments, a peak intensity ratio of the first peak wavelength to the second peak wavelength ranging from about 0 to about 40 corresponds to the first chromaticity (x, y) coordinates ranging from about (0.6, 0.4) to about (0.7, 0.3), respectively.

According to some embodiments, an optical density of the NS-based CC layer ranging from about 0 to about 3.0 corresponds to the first chromaticity (x, y) coordinates ranging from about (0.6, 0.4) to about (0.7, 0.3), respectively.

According to some embodiments, an optical transmission of the microLED ranging from about 100% to about 1% at the second peak wavelength corresponds to an optical density of the NS-based CC layer ranging from about 0 to about 3.0.

According to some embodiments, the emission spectrum corresponds to a single color point having a first chromaticity (x, y) coordinates along a coordinate line between a second chromaticity (x, y) coordinates of about (0.5, 0.5) and a third chromaticity (x, y) coordinates of about (0.7, 0.3) of an RGB color space.

According to some embodiments, the microLED has an optical transmission of about 1% to about 70% at the second peak wavelength through the NS-based CC layer.

According to some embodiments, the NS-based CC layer includes a surface area of about 0.5 μm×about 0.5 μm to about 1000 μm×about 1000 μm.

According to some embodiments, the NS-based CC layer covers an entire top surface area of the microLED.

According to some embodiments, a top surface area of the NS-based CC layer is greater than a top surface area of the microLED.

According to some embodiments, the NS-based CC layer includes a thickness of about 5 μm to about 40 μm.

According to some embodiments, the NS-based CC layer includes an optical density of about 0.1 to about 3.0.

According to some embodiments, the display device further includes a second sub-pixel including a second microLED disposed on the substrate. The second microLED is configured to emit a second display light having an emission spectrum including a single peak wavelength in a wavelength range of about 495 nm to about 570 of an electromagnetic (EM) spectrum.

According to some embodiments, the display device further includes a second sub-pixel including a second microLED disposed on the substrate. The second microLED is configured to emit a second display light having an emission spectrum including a single peak wavelength in a wavelength range of about 435 nm to about 495 nm of an electromagnetic (EM) spectrum.

According to some embodiments, a display device includes a substrate, a first sub-pixel configured to emit a first display light having a first emission spectrum including a first peak wavelength and a second peak wavelength, and a second sub-pixel is configured to emit a second display light having a second emission spectrum including a third peak wavelength and a fourth peak wavelength. The first sub-pixel includes a first microLED disposed on the substrate and a first nanostructure-based color conversion (NS-based CC) layer disposed on the first microLED. The first NS-based CC layer includes a first set of quantum dots (QDs) configured to emit a first light having the first peak wavelength. The first microLED is configured to emit a second light having the second peak wavelength. The second sub-pixel includes a second microLED disposed on the substrate and a second NS-based CC layer disposed on the second microLED. The second NS-based CC layer includes a second set of quantum dots (QDs) configured to emit a third light having the third peak wavelength. The second microLED is configured to emit a fourth light having the fourth peak wavelength.

According to some embodiments, the first emission spectrum corresponds to a first color point having a first chromaticity (x, y) coordinates on an RGB color space, and the second emission spectrum corresponds to a second color point having a second chromaticity (x, y) coordinates on the RGB color space. The second chromaticity (x, y) coordinates is different from the first chromaticity (x, y) coordinates.

According to some embodiments, the first and third peak wavelengths are in a wavelength range of about 620 nm to about 750 nm.

According to some embodiments, the second and fourth peak wavelengths are in a wavelength range of about 550 nm to about 610 nm.

According to some embodiments, an optical density of the first NS-based CC layer is different from an optical density of the second NS-based CC layer.

According to some embodiments, a thickness of the first NS-based CC layer is different from a thickness of the second NS-based CC layer.

According to some embodiments, a concentration of the first set of QDs is different from a concentration of the second set of QDs.

According to some embodiments, a first portion of the second light is absorbed by the first set of QDs and down-converted to the first light, and a second portion of the second light is transmitted through the first NS-based CC layer.

According to some embodiments, a first portion of the fourth light is absorbed by the second set of QDs and down-converted to the third light, and a second portion of the fourth light is transmitted through the second NS-based CC layer.

According to some embodiments, the first microLED has a first optical transmission of about 1% to about 70% at the second peak wavelength through the first NS-based CC layer, and the second microLED has a second optical transmission of about 1% to about 70% at the fourth peak wavelength through the second NS-based CC layer. The second optical transmission is different from the first optical transmission.

According to some embodiments, a method of fabricating a display device includes forming first and second microLEDs on a substrate, depositing a layer of quantum dots (QDs) on the first and second microLEDs, masking a first portion of the layer of QDs, performing a hardening process on a second portion of the layer of QDs, and removing the first portion of the layer of QDs. The first microLED is formed to emit a first display light having a first emission spectrum with a dual peak wavelength and the second microLED is formed to emit a second display light having a second emission spectrum with a single peak wavelength.

According to some embodiments, depositing the layer of QDs includes spin-coating, slot-die coating, doctor blade coating, or draw bar coating a solution of the QDs on the first and second microLEDs.

According to some embodiments, masking the first portion of the layer of QDs includes selectively forming a photoresist layer on the first portion of the layer of QDs on the second microLED.

According to some embodiments, performing the hardening process on the second portion of the layer of QDs includes curing the second portion of the layer of QDs on the first microLED with an ultra-violet radiation.

According to some embodiments, removing the first portion of the layer of QDs includes washing the first portion of the layer of QDs in an alkaline solution.

According to some embodiments, a method of fabricating a display device includes forming first and second microLEDs on a substrate, forming a patterned template on the first and second microLEDs, depositing a layer of quantum dots (QDs) on the patterned template, masking a first portion of the layer of QDs, performing a hardening process on a second portion of the layer of QDs, and removing the first portion of the layer of QDs. The first microLED is formed to emit a first display light having a first emission spectrum with a dual peak wavelength and the second microLED is formed to emit a second display light having a second emission spectrum with a single peak wavelength. The patterned template includes an opening on the first microLED.

According to some embodiments, forming the patterned template includes depositing a polymer layer on the first and second microLEDs and patterning the polymer layer to form the opening on the first microLED.

According to some embodiments, depositing the layer of QDs includes spin-coating, slot-die coating, doctor blade coating, or draw bar coating a solution of the QDs on the patterned template.

According to some embodiments, performing the hardening process on the second portion of the layer of QDs includes curing the second portion of the layer of QDs that is disposed in the opening with an ultra-violet radiation.

According to some embodiments, removing the first portion of the layer of QDs comprises washing the first portion of the layer of QDs in toluene.

Further features and advantages of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the present embodiments and, together with the description, further serve to explain the principles of the present embodiments and to enable a person skilled in the relevant art(s) to make and use the present embodiments.

FIG. 1 is a 1931 CIE chromaticity diagram showing the color gamut for the Digital Cinema Initiatives (DCI) color space.

FIG. 2A illustrates a top-down view of a display device with microLED-based sub-pixels, according to some embodiments.

FIGS. 2B-2F illustrate different cross-sectional views of a display device with microLED-based sub-pixels, according to some embodiments.

FIGS. 3A-4B and 5 illustrate optical characteristics of a display device with microLED-based sub-pixels, according to some embodiments.

FIG. 6 is a flow diagram of a method for fabricating a display device with microLED-based sub-pixels, according to some embodiments.

FIGS. 7-10 illustrate cross-sectional views of a display device with microLED-based sub-pixels at various stages, according to some embodiments.

FIG. 11 is a flow diagram of another method for fabricating a display device with microLED-based sub-pixels, according to some embodiments.

FIGS. 12-17 illustrate cross-sectional views of a display device with microLED-based sub-pixels at various stages, according to some embodiments.

FIG. 18 illustrates a cross-sectional view of a nanostructure, according to some embodiments.

FIG. 19 illustrates a top-down view a nanostructure film, according to some embodiments.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements. The discussion of elements with the same annotations applies to each other, unless mentioned otherwise. The drawings provided throughout the disclosure should not be interpreted as to-scale drawings, unless mentioned otherwise.

### DETAILED DESCRIPTION OF THE INVENTION

Although specific configurations and arrangements may be discussed, it should be understood that this is done for illustrative purposes only. A person skilled in the pertinent art will recognize that other configurations and arrangements can be used without departing from the spirit and scope of the present invention. It will be apparent to a person skilled in the pertinent art that this invention can also be employed in a variety of other applications beyond those specifically mentioned herein. It should be appreciated that the particular implementations shown and described herein are examples and are not intended to otherwise limit the scope of the application in any way.

It is noted that references in the specification to “one embodiment,” “an embodiment,” “an example embodiment,” etc., indicate that the embodiment described can include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

All numbers in this description indicating amounts, ratios of materials, physical properties of materials, and/or use are to be understood as modified by the word “about,” except as otherwise explicitly indicated.

In some embodiments, the terms “about” and “substantially” can indicate a value of a given quantity that varies within 5% of the value (e.g., ±1%, ±2%, ±3%, ±4%, ±5% of the value). These values are merely examples and are not intended to be limiting. The terms “about” and “substantially” can refer to a percentage of the values as interpreted by those skilled in relevant art(s) in light of the teachings herein.

In some embodiments, the term “display device” refers to an arrangement of elements that allow for the visible representation of data on a display screen. Suitable display screens can include various flat, curved or otherwise-shaped screens, films, sheets or other structures for displaying information visually to a user. Display devices described herein can be included in, for example, display systems encompassing a liquid crystal display (LCD), televisions, computers, mobile phones, smart phones, personal digital assistants (PDAs), gaming devices, electronic reading devices, digital cameras, tablets, wearable devices, car navigation systems, and the like.

In some embodiments, the term “nanostructure” refers to a structure having at least one region or characteristic dimension with a dimension of less than about 500 nm. In some embodiments, the nanostructure has a dimension of less than about 200 nm, less than about 100 nm, less than about 50 nm, less than about 20 nm, or less than about 10 nm. Typically, the region or characteristic dimension will be along the smallest axis of the structure. Examples of such structures include nanowires, nanorods, nanotubes, branched nanostructures, nanotetrapods, tripods, bipods, nanocrystals, nanodots, QDs, nanoparticles, and the like. Nanostructures can be, e.g., substantially crystalline, substantially monocrystalline, polycrystalline, amorphous, or a combination thereof. In some embodiments, each of the three dimensions of the nanostructure has a dimension of less than about 500 nm, less than about 200 nm, less than about 100 nm, less than about 50 nm, less than about 20 nm, or less than about 10 nm.

In some embodiments, the term “QD” or “nanocrystal” refers to nanostructures that are substantially monocrystalline. A nanocrystal has at least one region or characteristic dimension with a dimension of less than about 500 nm, and down to the order of less than about 1 nm. The terms “nanocrystal,” “QD,” “nanodot,” and “dot,” are readily understood by the ordinarily skilled artisan to represent like structures and are used herein interchangeably. The present invention also encompasses the use of polycrystalline or amorphous nanocrystals.

In some embodiments, the term “diameter” of a nanostructure refers to the diameter of a cross-section normal to a first axis of the nanostructure, where the first axis has the greatest difference in length with respect to the second and third axes (the second and third axes are the two axes whose lengths most nearly equal each other). The first axis is not necessarily the longest axis of the nanostructure; e.g., for a disk-shaped nanostructure, the cross-section would be a substantially circular cross-section normal to the short longitudinal axis of the disk. Where the cross-section is not circular, the diameter is the average of the major and minor axes of that cross-section. For an elongated or high aspect ratio nanostructure, such as a nanowire, the diameter is measured across a cross-section perpendicular to the longest axis of the nanowire. For a spherical nanostructure, the diameter is measured from one side to the other through the center of the sphere.

In some embodiments, the terms “crystalline” or “substantially crystalline,” when used with respect to nanostructures, refer to the fact that the nanostructures typically exhibit long-range ordering across one or more dimensions of the structure. It will be understood by one of skill in the art that the term “long range ordering” will depend on the absolute size of the specific nanostructures, as ordering for a single crystal cannot extend beyond the boundaries of the crystal. In this case, “long-range ordering” will mean substantial order across at least the majority of the dimension of the nanostructure. In some instances, a nanostructure can bear an oxide or other coating, or can be comprised of a core and at least one shell. In such instances it will be appreciated that the oxide, shell(s), or other coating can but need not exhibit such ordering (e.g. it can be amorphous, polycrystalline, or otherwise). In such instances, the phrase “crystalline,” “substantially crystalline,” “substantially monocrystalline,” or “monocrystalline” refers to the central core of the nanostructure (excluding the coating layers or shells). The terms “crystalline” or “substantially crystalline” as used herein are intended to also encompass structures comprising various defects, stacking faults, atomic substitutions, and the like, as long as the structure exhibits substantial long range ordering (e.g., order over at least about 80% of the length of at least one axis of the nanostructure or its core). In addition, it will be appreciated that the interface between a core and the outside of a nanostructure or between a core and an adjacent shell or between a shell and a second adjacent shell can contain non-crystalline regions and can even be amorphous. This does not prevent the nanostructure from being crystalline or substantially crystalline as defined herein.

In some embodiments, the term “monocrystalline” when used with respect to a nanostructure indicates that the nanostructure is substantially crystalline and comprises substantially a single crystal. When used with respect to a nanostructure heterostructure comprising a core and one or more shells, “monocrystalline” indicates that the core is substantially crystalline and comprises substantially a single crystal.

In some embodiments, the term “ligand” refers to a molecule capable of interacting (whether weakly or strongly) with one or more faces of a nanostructure, e.g., through covalent, ionic, van der Waals, or other molecular interactions with the surface of the nanostructure.

In some embodiments, the term “quantum yield” (QY) refers to the ratio of photons emitted to photons absorbed, e.g., by a nanostructure or population of nanostructures. As known in the art, quantum yield is typically determined by a comparative method using well-characterized standard samples with known quantum yield values.

In some embodiments, the term “primary emission peak wavelength” refers to the wavelength at which the emission spectrum exhibits the highest intensity.

In some embodiments, the term “full width at half-maximum” (FWHM) refers to a measure of spectral width. In the case of an emission spectrum, a FWHM can refer to a width of the emission spectrum at half of a peak intensity value.

In some embodiments, the terms “luminance” and “brightness” are used herein interchangeably and refer to a photometric measure of a luminous intensity per unit area of a light source or an illuminated surface.

In some embodiments, the term “nanostructure (NS) film” refers to a film having luminescent nanostructures.

In some embodiments, the term “red sub-pixel” refers to an area of a pixel and/or a display device that emits light. This light can have a primary emission peak wavelength in a wavelength range of about 550 nm to about 750 nm of the electromagnetic (EM) spectrum. Additionally, or alternatively, the device can emit light having chromaticity (x, y) coordinates along a line between chromaticity (x, y) coordinates of about (0.5, 0.5) and chromaticity (x, y) coordinates of about (0.7, 0.3) of the 1931 CIE chromaticity diagram.

In some embodiments, the term “green sub-pixel” refers to an area of a pixel and/or a display device that emits light having a primary emission peak wavelength in a wavelength range of about 495 nm to about 570 nm of the EM spectrum.

In some embodiments, the term “blue sub-pixel” refers to an area of a pixel and/or a display device that emits light having a primary emission peak wavelength in a wavelength range of about 435 nm to about 495 nm of the EM spectrum.

The published patents, patent applications, websites, company names, and scientific literature referred to herein are hereby incorporated by reference in their entirety to the same extent as if each was specifically and individually indicated to be incorporated by reference. Any conflict between any reference cited herein and the specific teachings of this specification shall be resolved in favor of the latter. Likewise, any conflict between an art-understood definition of a word or phrase and a definition of the word or phrase as specifically taught in this specification shall be resolved in favor of the latter.

Technical and scientific terms used herein have the meaning commonly understood by one of skill in the art to which the present application pertains, unless otherwise defined. Reference is made herein to various methodologies and materials known to those of skill in the art.

### Example Embodiments of a Display Device

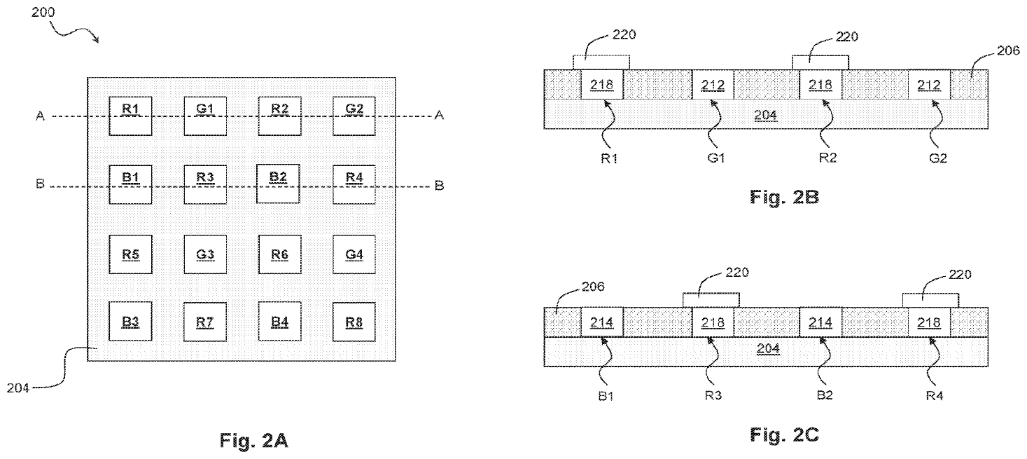

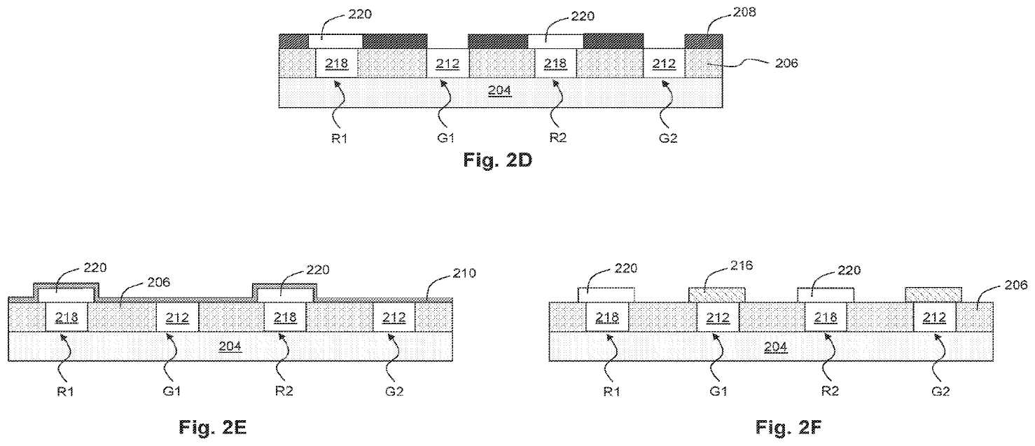

FIG. 2A illustrates a top-down view of a microLED-based display device 200, according to some embodiments. FIGS. 2B and 2D-2F illustrate different cross-sectional views of microLED-based display device 200 along a line A-A of FIG. 2A. FIG. 2C illustrates a cross-sectional views of microLED-based display device 200 along a line B-B of FIG. 2A. FIGS. 2B-2F illustrate cross-sectional views of microLED-based display device 200 with additional structures that are not shown in FIG. 2A for simplicity. The discussion of elements with the same annotations applies to each other, unless mentioned otherwise.

Referring to FIG. 2A, in some embodiments, microLED-based display device 200 can include red sub-pixels R1-R8, green sub-pixels G1-G4, and blue sub-pixels B1-B4 disposed on a substrate 204. The number and arrangement of red, green, and blue sub-pixels in microLED-based display device 200 shown in FIG. 2A are exemplary, and are not limiting. MicroLED-based display device 200 can have any number and any arrangement of red, green, and blue sub-pixels. The discussion of (i) red sub-pixels R1 applies to red sub-pixels R2-R8, (ii) green sub-pixels G1 applies to green sub-pixels G2-G4, and (iii) blue sub-pixels B1 applies to blue sub-pixels B2-B4, unless mentioned otherwise.

In some embodiments, microLED-based display device 200 can further include a dielectric layer 206 disposed between red sub-pixels R1-R8, green sub-pixels G1-G4, and blue sub-pixels B1-B4 and on substrate 204, as shown in FIGS. 2B-2F. Dielectric layer 206 can electrically and/or optically isolate red sub-pixels R1-R8, green sub-pixels G1-G4, and blue sub-pixels B1-B4 from each other. In some embodiments, microLED-based display device 200 can additionally or optionally include a light blocking layer 208 (also referred to as a “black matrix layer 208”) disposed on dielectric layer 206, as shown in FIG. 2D. Light blocking layer 208 can prevent or minimize optical cross-talk between red sub-pixels R1-R8, green sub-pixels G1-G4, and blue sub-pixels B1-B4. In some embodiments, microLED-based display device 200 can additionally or optionally include an encapsulation layer 210, as shown in FIG. 2E. In some embodiments, encapsulation layer 210 can be disposed on the structures of FIGS. 2D and 2F. Encapsulation layer 210 can include an insulation oxide layer, such as aluminum oxide to provide environmental sealing to the underlying layers and/or structures of microLED-based display device 200.

Referring to FIGS. 2A-2B and 2D-2F, in some embodiments, each of green sub-pixels G1-G4 can include a microLED 212 that can emit a green light having a primary emission PWL of about 495 nm to about 570 nm in the visible spectrum. Referring to FIGS. 2A and 2C, in some embodiments, each of blue sub-pixels B1-B4 can include a microLED 214 that can emit a blue light having a primary emission PWL of about 435 nm to about 495 nm in the visible spectrum. In some embodiments, green sub-pixels G1-G4 and/or blue sub-pixels B1-B4 can include color filters 216, such as shown in FIG. 2F. Color filters 216 can tune the spectral emission widths of the light emitted from microLEDs 212 and/or 214 to achieve a desired color gamut on the 1931 CIE color space. In some embodiments, instead of color filters 216, green sub-pixels G1-G4 and/or blue sub-pixels B1-B4 can include optically transparent substrates.

Referring to FIGS. 2A-2B and 2D-2F, in some embodiments, each of red sub-pixels R1-R8 can include a microLED 218 disposed on substrate 204 and a NS-based CC layer 220 disposed on microLED 218. MicroLED 218 can be an indium gallium nitride (InGaN) microLED configured to emit a light having a primary emission PWL of about 550 nm to about 610 nm, a FWHM of about 20 nm to about 30 nm, and a high color brightness of about 25,000 nits to about 50,000 nits or greater than about 50,000 nits at a high current density equal to or higher than about 4 A/cm². The light having a primary emission PWL of about 550 nm to about 610 nm can correspond to a yellow, an orange, or an amber light of the visible spectrum.

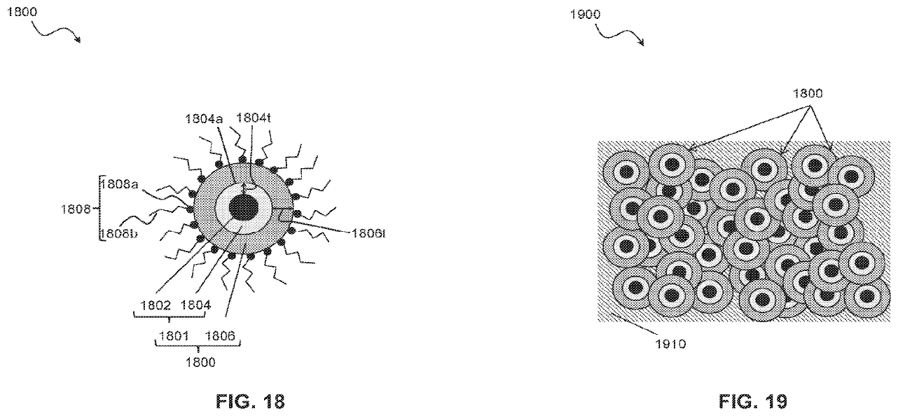

In some embodiments, NS-based CC layer 220 can include luminescent nanostructures such as QDs (e.g., QD 1800 described with reference to FIG. 18) disposed in a matrix material (e.g., matrix material 1910 described with reference to FIG. 19). The luminescent nanostructures can have a primary emission PWL of about 620 nm to about 750 nm and a FWHM of about 10 nm to about 40 nm, which can correspond to a red light, according to some embodiments. In some embodiments, the luminescent nanostructures can include indium phosphide (InP)- or cadmium selenide (CdSe)-based QDs having a QY of about 65% to about 80%. In some embodiments, red sub-pixels R1-R8 can further include other optically transparent insulating or conductive layers (not shown) between NS-based CC layer 220 and microLED 218.

In some embodiments, substrate 204 can include circuitry (not shown) to control microLEDs 212, 214, and 218. Each of microLEDs 212, 214, and 218 can have lateral dimensions less than about 100 μm. The structure of microLEDs 212, 214, and 218 can be based on a p-n junction diode having direct bandgap semiconductor materials, such as binary III-V (e.g., GaN) compounds, ternary III-V compounds (e.g., InGaN), quaternary III-V compounds (e.g. AlInGaN), or a combination thereof.

In some embodiments, each NS-based CC layer 220 can have a thickness of about 5 μm to about 40 μm to adequately output light with the desired PWL and the desired color point from each of red sub-pixels R1-R8, as described in detail below. Each NS-based CC layer 220 can have a surface area to cover the entire top surface area of each of microLEDs 218 to minimize or prevent optical cross-talk between microLEDs 212, 214, and 218. In some embodiments, each NS-based CC layer 220 can have a surface area of about 0.5 μm×about 0.5 μm to about 1000 μm×about 1000 μm (e.g., about 2 μm×2 μm to about 100 μm×100 μm).

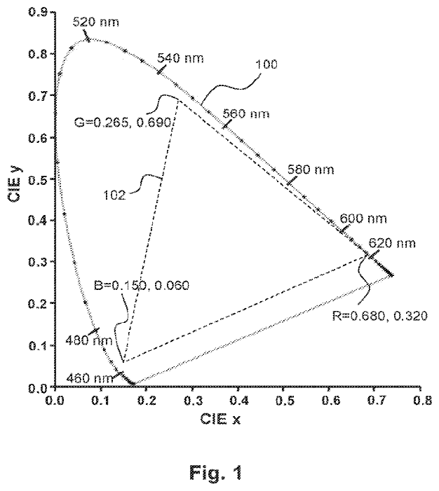

In each of red sub-pixels R1-R8, a first portion of the light from microLED 218 can be absorbed by the luminescent nanostructures of NS-based CC layer 220 and re-emitted as a light having the primary emission PWL of the luminescent nanostructures. A second portion of the light from microLED 218 can be allowed to transmit through NS-based CC layer 220. As a result, the light transmitted from each of red sub-pixels R1-R8 can have a dual PWL emission spectrum. In some embodiments, the dual PWL emission spectrum can include a first emission PWL corresponding to the primary emission PWL (e.g., about 620 nm to about 750 nm) of the luminescent nanostructures and a second emission PWL corresponding to the primary emission PWL (e.g., about 550 nm to about 610 nm) of the light transmitted from microLED 218. The dual PWL emission spectrum can correspond to a single color point (also referred to as a “blended color point”) on the 1931 CIE chromaticity diagram shown in FIG. 1. In some embodiments, the blended color point can be a red color point. Thus, with the use of NS-based CC layer 220 on microLED 218, light emission having a red color point on the 1931 CIE chromaticity diagram can be achieved from red sub-pixels R1-R8 without compromising the color brightness of about 25,000 nits to about 50,000 nits or greater than about 50,000 nits. Due to the challenges of microLEDs producing red light with such high color brightness, as discussed above, red sub-pixels may emit orange light for such high color brightness without the use of NS-based CC layer 220.

In some embodiments, the blended color point can have chromaticity (x, y) coordinates along a coordinate line between chromaticity (x, y) coordinates of about (0.5, 0.5) and chromaticity (x, y) coordinates of about (0.7, 0.3) of the 1931 CIE chromaticity diagram. The coordinate line can be a portion of spectrum locus 102 shown in FIG. 1. Based on the desired color point for red sub-pixels R1-R8, the blended color point for the light emitted from red sub-pixels R1-R8 can be varied along this coordinate line by varying the optical density of NS-based CC layer 220. Varying the optical density of NS-based CC layer 220 can vary (i) the percentage of light transmission from microLED 218 through NS-based CC layer 220, and (ii) the relative peak intensities of the first and second emission PWLs of the dual PWL emission spectrum.

The optical density of NS-based CC layer 220 can be varied by tuning the thickness of NS-based CC layer 220, the concentration of luminescent nanostructures in NS-based CC layer 220, and/or the concentration of scattering particles (described below with reference to FIG. 19) in NS-based CC layer 220. In some embodiments, NS-based CC layer 220 can be formed with an optical density of about 0.1 to about 3.0, which can allow about 70% to about 0.1% light transmission, respectively, at the primary emission PWL from microLED 218 through NS-based CC layer 220.

In some embodiments, the blended color point can be varied along the coordinate line by varying the first and second emission PWLs of the dual PWL emission spectrum. The first and second emission PWLs can be varied by varying the emission properties of microLED 218 and NS-based CC layer 220. In some embodiments, two or more of red sub-pixels R1-R8 can have (i) NS-based CC layers 220 with optical densities different from each other, (ii) NS-based CC layers 220 with concentrations of luminescent nanostructures different from each other, and/or (iii) microLEDs 218 operating at different current densities and emitting light at primary emission PWLs different from each other in a wavelength range of about 550 nm to about 610 nm. As a result, two or more of red sub-pixels R1-R8 can emit light having dual PWL emission spectra and corresponding blended color points different from each other.

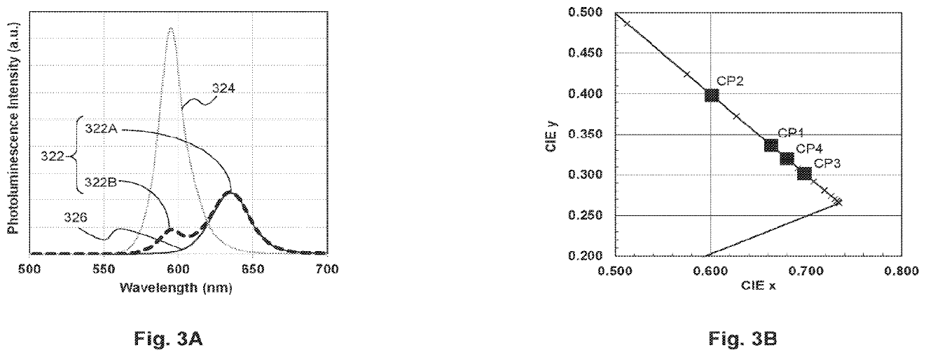

FIG. 3A shows an example dual PWL emission spectrum 322 of one or more of red sub-pixels R1-R8 and FIG. 3B shows corresponding blended color point CP1 on a portion of the 1931 CIE chromaticity diagram. In this example, (i) NS-based CC layer 220 can have an optical density of about 1.0 and a thickness of about 5 μm, (ii) microLED 218 can have a primary emission PWL of about 595 nm and an optical transmission of about 10% at PWL of about 595 nm, and (iii) luminescent nanostructures can have a primary emission PWL of about 640 and a FWHM of about 30 nm. Dual PWL emission spectrum 322 can include a first emission PWL 322A at about 640 nm and a second emission PWL 322B at about 595 nm. The peak intensity ratio of first emission PWL 322A to second emission PWL 322B can be about 3.36. Dual PWL emission spectrum 322 with the peak intensity ratio of about 3.36 can correspond to blended color point CP1 having chromaticity (x, y) coordinates of about (0.663, 0.336), which is a red color point on the 1931 CIE color space as perceived by the human eye. As shown in FIG. 3B, color point CP1 corresponding to dual PWL emission spectrum 322 is similar to the color point that corresponds to a single PWL emission spectrum having PWL in a wavelength range of about 615 to about 620 nm.

FIGS. 3A-3B also shows an example emission spectrum 324 of the light emitted from microLED 218 without transmitting through NS-based CC layer 220 (i.e., 100% light transmission at the primary emission PWL from microLED 218) and color point CP2 corresponding to emission spectrum 324. Color point CP2 has chromaticity (x, y) coordinates of about (0.601, 0.398), which is an orange color point on the 1931 CIE color space.

FIGS. 3A-3B further shows an example emission spectrum 326 of luminescent nanostructures in NS-based CC layer 220 without microLED 218 and color point CP3 corresponding to emission spectrum 326. Color point CP3 has chromaticity (x, y) coordinates of about (0.698, 0.302). FIG. 3B also shows color point CP4 for the red color of the DCI Specification, which has chromaticity (x, y) coordinates of about (0.680, 0.320).

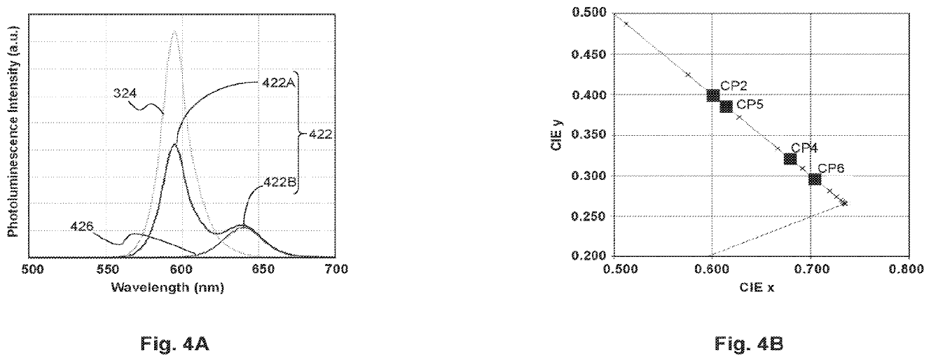

FIG. 4A shows another example dual PWL emission spectrum 422 of one or more of red sub-pixels R1-R8 and FIG. 4B shows corresponding blended color point CP5 on a portion of the 1931 CIE chromaticity diagram. The configuration of red sub-pixels R1-R8 in this example is different from that shown in FIGS. 3A-3B. In this example, (i) NS-based CC layer 220 can have an optical density of about 0.3 and a thickness of about 5 μm, (ii) microLED 218 can have a primary emission PWL of about 595 nm and an optical transmission of about 50% at PWL of about 595 nm, and (iii) luminescent nanostructures can have a primary emission PWL of about 640 and a FWHM of about 30 nm.

Similar to dual PWL emission spectrum 322, dual PWL emission spectrum 422 can have first emission PWL 422A at about 640 nm and a second emission PWL 422B at about 595 nm. However, due to different optical densities of NS-based CC layer 220 in examples of FIGS. 3A-3B and 4A-4B, the peak intensity ratio of first emission PWL 322A to second emission PWL 322B is different from the peak intensity ratio of first emission PWL 422A to second emission PWL 422B. As a result, blended color point CP5 of FIG. 4B is different from blended color point CP1 of FIG. 3B. The peak intensity ratio of first emission PWL 422A to second emission PWL 422B can be about 0.37 and blended color point CP5 has chromaticity (x, y) coordinates of about (0.615, 0.385).

FIGS. 4A-4B further show an example emission spectrum 426 of luminescent nanostructures in NS-based CC layer 220 without microLED 218 and color point CP5 corresponding to emission spectrum 326. Emission spectrum 326 and 426 can be different due to different configurations of NS-based CC layer 220.

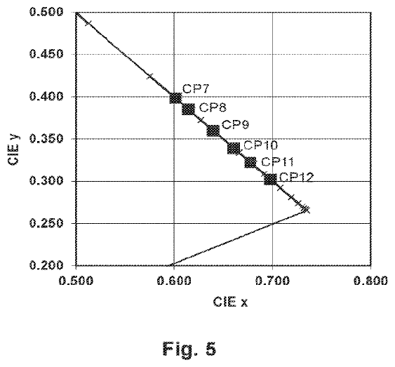

FIG. 5 shows different examples of blended color points CP7-CP12 on a portion of the 1931 CIE chromaticity diagram for different optical densities of NS-based CC layer 220 presented in Table 1 below.

TABLE 1

| | | | | | Peak intensity ratio |
|---|---|---|---|---|---|
| | | | | % Transmission of | of first emission |
| Blended Color Points | Chromaticity | | | light at emission | PWL to second |
| corresponding to | Coordinates | | Optical | PWL from | emission PWL of |
| dual PWL emission | of Blended | | Density of | microLED 218 | dual PWL emission |
| spectrum of red | Color Points | | NS-based CC | through NS-based | spectrum of red |
| sub-pixels R1-R8 | CIE x | CIE y | layer 220 | CC layer 220 | sub-pixels R1-R8 |
| CP7 | 0.601 | 0.398 | 0 | 100% | 0.00 |
| CP8 | 0.615 | 0.385 | 0.3 | 50% | 0.37 |
| CP9 | 0.640 | 0.360 | 0.7 | 20% | 1.49 |
| CP10 | 0.660 | 0.339 | 1.0 | 10% | 3.36 |
| CP11 | 0.678 | 0.322 | 1.3 | 5% | 7.09 |
| CP12 | 0.698 | 0.302 | 2.0 | 1% | 36.94 |

In some embodiments, microLED display device 200 can include other elements, such as display screen, diffuser layers, and buffer layers, which are not shown for simplicity.

### Example Methods for Fabricating a Display Device

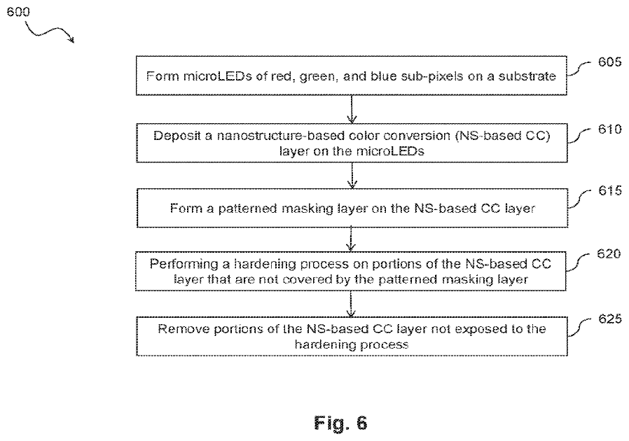

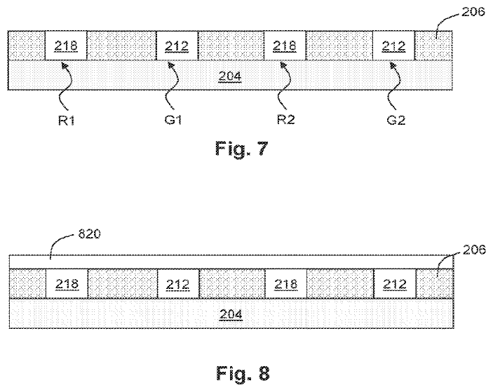

FIG. 6 is a flow diagram of an example method 600 for fabricating microLED-based display device 200, according to some embodiments. For illustrative purposes, the operations illustrated in FIG. 6 will be described with reference to the example fabrication process for fabricating microLED-based display device 200 as illustrated in FIGS. 2A-2C. FIGS. 7-10 are cross-sectional views of microLED-based display device 200 at various stages of fabrication, according to some embodiments. Operations can be performed in a different order or not performed depending on specific applications. It should be noted that method 600 may not produce a complete microLED-based display device 200. Accordingly, it is understood that additional processes can be provided before, during, and after method 600, and that some other processes may only be briefly described herein. Elements in FIGS. 7-10 with the same annotations as elements in FIGS. 2A-2C are described above.

In step 605, microLEDs of red, green, and blue sub-pixels are formed on a substrate. For example, as shown in FIG. 7, microLEDs 212 and 218 are formed on substrate 204. MicroLEDs 214 are also formed, but are not visible in cross-sectional view of FIG. 7. After the formation of microLEDs 212, 214, and 218, dielectric layer 206 can be formed on substrate 204, as shown in FIG. 7.

Referring to FIG. 6, in step 610, an NS-based CC layer is deposited on the microLEDs. For example, as shown in FIG. 8, NS-based CC layer 820 is deposited on the structure of FIG. 7. Similar to NS-based CC layer 220, NS-based CC layer 820 can include luminescent nanostructures, such QDs in a UV curable matrix material. In some embodiments, NS-based CC layer 820 can be deposited by preparing a solution of the luminescent nanostructures and spin-coating the solution on the structure of FIG. 7. In some embodiments, the solution of the luminescent nanostructures can include tetraacrylate monomer.

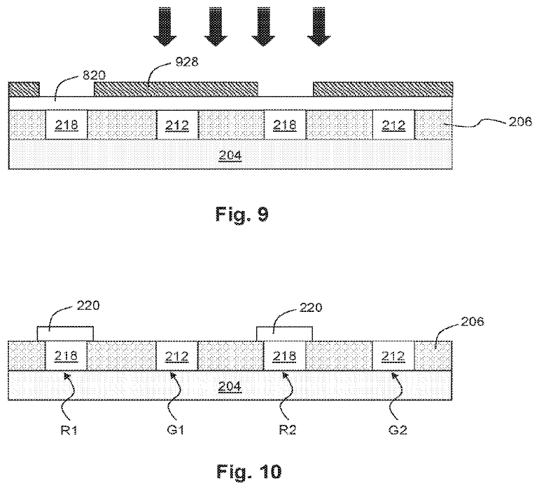

Referring to FIG. 6, in step 615, a patterned masking layer is formed on the NS-based CC layer. For example, as shown in FIG. 9, a patterned masking layer 928 is formed on the structure of FIG. 8. In some embodiments, patterned masking layer 928 can include a photoresist, or any other suitable patternable masking material, as would become apparent to persons skilled in the art. Patterned masking layer 928 can be formed by a photolithographic process.

Referring to FIG. 6, in step 620, a hardening process is performed on portions of the NS-based CC layer that are not covered by the patterned masking layer. For example, as shown in FIG. 9, a hardening process is performed on the portions of NS-based CC layer 820 that are not covered by patterned masking layer 928. The hardening process can include curing the exposed portions of NS-based CC layer 820 with ultra-violet (UV) radiation in air at a temperature of about 100° C. to about 180° C. for a time duration of about 60 min to about 120 min.

Referring to FIG. 6, in step 625, portions of the NS-based CC layer not exposed to the hardening process are removed. For example, as shown in FIG. 10, the portions of NS-based CC layer 820 underlying patterned masking layer 928 during the hardening process of step 620 are removed to form NS-based CC layers 220 on microLEDs 218. These uncured portions of NS-based CC layer 820 can be removed by washing the structure of FIG. 9 with an alkaline solution after the hardening process.

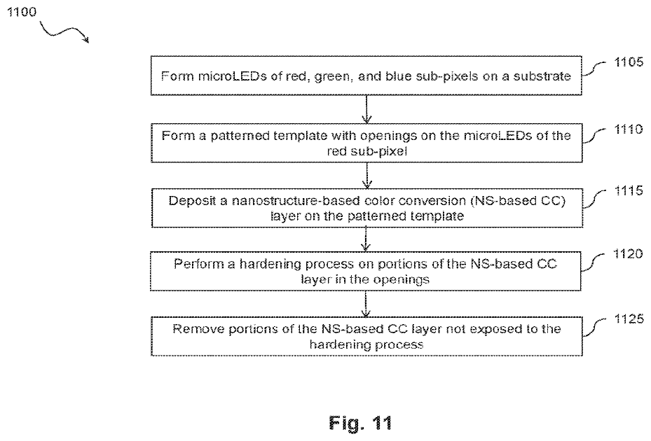

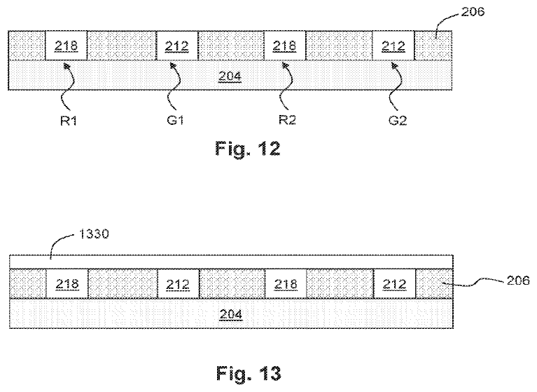

FIG. 11 is a flow diagram of another example method 1100 for fabricating microLED-based display device 200, according to some embodiments. For illustrative purposes, the operations illustrated in FIG. 11 will be described with reference to the example fabrication process for fabricating microLED-based display device 200 as illustrated in FIGS. 2A-2C. FIGS. 12-17 are cross-sectional views of microLED-based display device 200 at various stages of fabrication, according to some embodiments. Operations can be performed in a different order or not performed depending on specific applications. It should be noted that method 1100 may not produce a complete microLED-based display device 200. Accordingly, it is understood that additional processes can be provided before, during, and after method 1100, and that some other processes may only be briefly described herein. Elements in FIGS. 12-17 with the same annotations as elements in FIGS. 2A-2C and FIGS. 7-10 are described above.

In step 1105, microLEDs of red, green, and blue sub-pixels are formed on a substrate. For example, as shown in FIG. 12, microLEDs 212 and 218 are formed on substrate 204. MicroLEDs 214 are also formed, but are not visible in cross-sectional view of FIG. 12. After the formation of microLEDs 212, 214, and 218, dielectric layer 206 can be formed on substrate 204, as shown in FIG. 12.

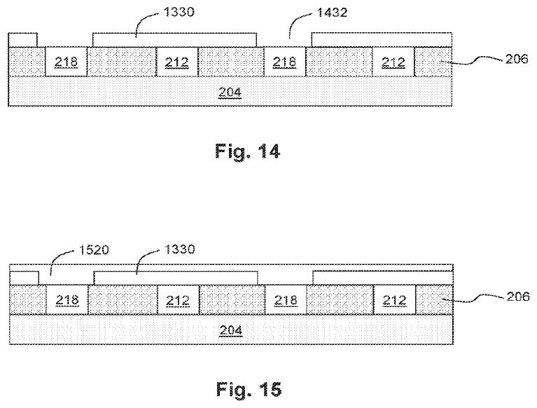

Referring to FIG. 11, in step 1110, a patterned template with openings on the microLEDs of the red sub-pixel are formed. For example, as described with reference to FIGS. 13-14, a patterned template 1330 with openings 1432 is formed on the structure of FIG. 12. The formation of patterned template 1330 can include depositing a photoresist layer 1330 on the structure of FIG. 12, as shown in FIG. 13, and performing photolithographic process on the structure of FIG. 13 to form openings 1432, as shown in FIG. 14.

Referring to FIG. 11, in step 1115, an NS-based CC layer is deposited on the patterned template. For example, as shown in FIG. 15, NS-based CC layer 1520 is deposited on the structure of FIG. 14. Similar to NS-based CC layer 220, NS-based CC layer 1520 can include luminescent nanostructures, such QDs in a UV curable matrix material. In some embodiments, NS-based CC layer 1520 can be deposited by preparing a solution of the luminescent nanostructures and spin-coating the solution on the structure of FIG. 14. In some embodiments, the solution of the luminescent nanostructures can include tetraacrylate monomer.

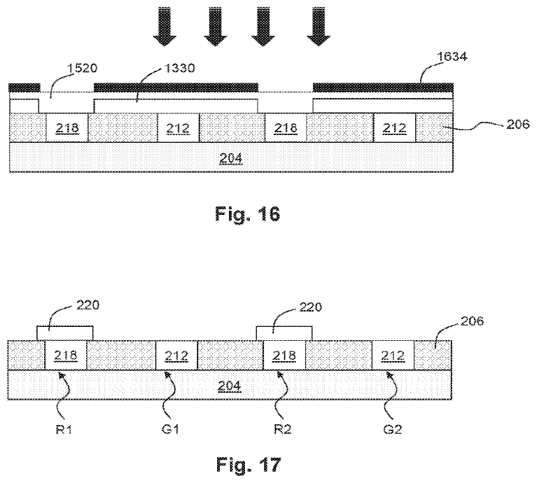

Referring to FIG. 11, in step 1120, a hardening process is performed on portions of the NS-based CC layer in the openings. For example, as shown in FIG. 16, a hardening process is performed on portions of NS-based CC layer 1520 in openings 1432. The hardening process can include sequential operation of (i) masking portions of NS-based CC layer 1520 on patterned template 1330 with a masking layer 1634, and (ii) curing the exposed portions of NS-based CC layer 1520 in openings 1432 with ultra-violet (UV) radiation in air at a temperature of about 100° C. to about 180° C. for a time duration of about 60 min to about 120 min.

Referring to FIG. 11, in step 1125, portions of the NS-based CC layer not exposed to the hardening process are removed. For example, as shown in FIG. 17, the portions of NS-based CC layer 1520 underlying masking layer 1634 during the hardening process of step 1120 are removed to form NS-based CC layers 220 on microLEDs 218. These uncured portions of NS-based CC layer 1520 can be removed by washing the structure of FIG. 16 with toluene after the hardening process.

### Example Embodiments of a Barrier Layer Coated Nanostructure

FIG. 18 illustrates a cross-sectional structure of a barrier layer coated luminescent nanostructure (NS) 1800, according to some embodiments. In some embodiments, a population of NS 1800 can be included in NS-based CC layer 136. Barrier layer coated NS 1800 includes a NS 1801 and a barrier layer 1806. NS 1801 includes a core 1802 and a shell 1804. Core 1802 includes a semiconducting material that emits light upon absorption of higher energies. Examples of the semiconducting material for core 1802 include indium phosphide (InP), cadmium selenide (CdSe), zinc sulfide (ZnS), lead sulfide (PbS), indium arsenide (InAs), indium gallium phosphide, (InGaP), cadmium zinc selenide (CdZnSe), zinc selenide (ZnSe) and cadmium telluride (CdTe). Any other II-VI, III-V, tertiary, or quaternary semiconductor structures that exhibit a direct band gap can be used as well. In some embodiments, core 1802 can also include one or more dopants such as metals, alloys, to provide some examples. Examples of metal dopant can include, but not limited to, zinc (Zn), Copper (Cu), aluminum (Al), platinum (Pt), chrome (Cr), tungsten (W), palladium (Pd), or a combination thereof. The presence of one or more dopants in core 1802 can improve structural and optical stability and QY of NS 1801 compared to undoped NSs.

Core 1802 can have a size of less than 20 nm in diameter, according to some embodiments. In another embodiment, core 1802 can have a size between about 1 nm and about 5 nm in diameter. The ability to tailor the size of core 1802, and consequently the size of NS 1801 in the nanometer range enables photoemission coverage in the entire optical spectrum. In general, the larger NSs emit light towards the red end of the spectrum, while smaller NSs emit light towards the blue end of the spectrum. This effect arises as larger NSs have energy levels that are more closely spaced than the smaller NSs. This allows the NS to absorb photons containing less energy, i.e. those closer to the red end of the spectrum.

Shell 1804 surrounds core 1802 and is disposed on outer surface of core 1802. Shell 1804 can include cadmium sulfide (CdS), zinc cadmium sulfide (ZnCdS), zinc selenide sulfide (ZnSeS), and zinc sulfide (ZnS). In some embodiments, shell 1804 can have a thickness 1804t, for example, one or more monolayers. In other embodiments, shell 1804 can have a thickness 1804t between about 1 nm and about 5 nm. Shell 1804 can be utilized to help reduce the lattice mismatch with core 1802 and improve the QY of NS 1801. Shell 1804 can also help to passivate and remove surface trap states, such as dangling bonds, on core 1802 to increase QY of NS 1801. The presence of surface trap states can provide non-radiative recombination centers and contribute to lowered emission efficiency of NS 1801.

In alternate embodiments, NS 1801 can include a second shell disposed on shell 1804, or more than two shells surrounding core 1802, without departing from the spirit and scope of the present invention. In some embodiments, the second shell can be on the order of two monolayers thick and is typically, though not required, also a semiconducting material. Second shell can provide protection to core 1802. Second shell material can be zinc sulfide (ZnS), although other materials can be used as well without deviating from the scope or spirit of the invention.

Barrier layer 1806 is configured to form a coating on NS 1801. In some embodiments, barrier layer 1806 is disposed on and in substantial contact with outer surface 1804a of shell 1804. In embodiments of NS 1801 having one or more shells, barrier layer 1806 can be disposed on and in substantial contact with the outermost shell of NS 1801. In an example embodiment, barrier layer 1806 is configured to act as a spacer between NS 1801 and one or more NSs in, for example, a solution, a composition, and/or a film having a plurality of NSs, where the plurality of NSs can be similar to NS 1801 and/or barrier layer coated NS 1800. In such NS solutions, NS compositions, and/or NS films, barrier layer 1806 can help to prevent aggregation of NS 1801 with adjacent NSs. Aggregation of NS 1801 with adjacent NSs can lead to increase in size of NS 1801 and consequent reduction or quenching in the optical emission properties of the aggregated NS (not shown) including NS 1801. In further embodiments, barrier layer 1806 provides protection to NS 1801 from, for example, moisture, air, and/or harsh environments (e.g., high temperatures and chemicals used during lithographic processing of NSs and/or during manufacturing process of NS based devices) that can adversely affect the structural and optical properties of NS 1801.

Barrier layer 1806 includes one or more materials that are amorphous, optically transparent and/or electrically inactive. Suitable barrier layers include inorganic materials, such as, but not limited to, inorganic oxides and/or nitrides. Examples of materials for barrier layer 1806 include oxides and/or nitrides of Al, Ba, Ca, Mg, Ni, Si, Ti, or Zr, according to various embodiments. Barrier layer 1806 can have a thickness 1806t ranging from about 8 nm to about 15 nm in various embodiments.

As illustrated in FIG. 18, barrier layer coated NS 1800 can additionally or optionally include a plurality of ligands or surfactants 1808, according to some embodiments. Ligands or surfactants 1808 can be adsorbed or bound to an outer surface of barrier layer coated NS 1800, such as on an outer surface of barrier layer 1806, according to some embodiments. The plurality of ligands or surfactants 1808 can include hydrophilic or polar heads 1808a and hydrophobic or non-polar tails 1808b. The hydrophilic or polar heads 1808a can be bound to barrier layer 1806. The presence of ligands or surfactants 1808 can help to separate NS 1800 and/or NS 1801 from other NSs in, for example, a solution, a composition, and/or a film during their formation. If the NSs are allowed to aggregate during their formation, the quantum efficiency of NSs such as NS 1800 and/or NS 1801 can drop. Ligands or surfactants 1808 can also be used to impart certain properties to barrier layer coated NS 1800, such as hydrophobicity to provide miscibility in non-polar solvents, or to provide reaction sites (e.g., reverse micellar systems) for other compounds to bind.

A wide variety of ligands exist that can be used as ligands 1808. In some embodiments, the ligand is a fatty acid selected from lauric acid, caproic acid, myristic acid, palmitic acid, stearic acid, and oleic acid. In some embodiments, the ligand is an organic phosphine or an organic phosphine oxide selected from trioctylphosphine oxide (TOPO), trioctylphosphine (TOP), diphenylphosphine (DPP), triphenylphosphine oxide, and tributylphosphine oxide. In some embodiments, the ligand is an amine selected from dodecylamine, oleylamine, hexadecylamine, and octadecylamine. In some embodiments, the ligand is trioctylphosphine (TOP). In some embodiments, the ligand is oleylamine. In some embodiments, the ligand is diphenylphosphine.

A wide variety of surfactants exist that can be used as surfactants 1808. Nonionic surfactants can be used as surfactants 1808 in some embodiments. Some examples of nonionic surfactants include polyoxyethylene (5) nonylphenylether (commercial name IGEPAL CO-520), polyoxyethylene (9) nonylphenylether (IGEPAL CO-630), octylphenoxy poly(ethyleneoxy) ethanol (IGEPAL CA-630), polyethylene glycol oleyl ether (Brij 93), polyethylene glycol hexadecyl ether (Brij 52), polyethylene glycol octadecyl ether (Brij S10), polyoxyethylene (10) isooctylcyclohexyl ether (Triton X-100), and polyoxyethylene branched nonylcyclohexyl ether (Triton N-101).

Anionic surfactants can be used as surfactants 1808 in some embodiments. Some examples of anionic surfactants include sodium dioctyl sulfosuccinate, sodium stearate, sodium lauryl sulfate, sodium monododecyl phosphate, sodium dodecylbenzenesulfonate, and sodium myristyl sulfate.

In some embodiments, NSs 1801 and/or 1800 can be synthesized to emit light in one or more various color ranges, such as red, orange, and/or yellow range. In some embodiments, NSs 1801 and/or 1800 can be synthesized to emit light in the green and/or yellow range. In some embodiments, NSs 1801 and/or 1800 can be synthesized emit light in the blue, indigo, violet, and/or ultra-violet range. In some embodiments, NSs 1801 and/or 1800 can be synthesized to have a primary emission peak wavelength between about 605 nm and about 650 nm, between about 510 nm and about 550 nm, or between about 300 nm and about 480 nm.

NSs 1801 and/or 1800 can be synthesized to display a high QY. In some embodiments, NSs 1801 and/or 1800 can be synthesized to display a QY between 80% and 95% or between 85% and 90%.

Thus, according to various embodiments, NSs 1800 can be synthesized such that the presence of barrier layer 1806 on NSs 1801 does not substantially change or quench the optical emission properties of NSs 1801.

### Example Embodiments of a Nanostructure Film

FIG. 19 illustrates a cross-sectional view of a NS film 1900, according to some embodiments. In some embodiments, NS-based CC layer 220 can be similar to NS film 1900.

NS film 1900 can include a plurality of barrier layer coated core-shell NSs 1800 (FIG. 18) and a matrix material 1910, according to some embodiments. NSs 1800 can be embedded or otherwise disposed in matrix material 1910, according to some embodiments. As used herein, the term “embedded” is used to indicate that the NSs are enclosed or encased within matrix material 1910 that makes up the majority component of the matrix. It should be noted that NSs 1800 can be uniformly distributed throughout matrix material 1910 in some embodiments, though in other embodiments NSs 1800 can be distributed according to an application-specific uniformity distribution function. It should be noted that even though NSs 1800 are shown to have the same size in diameter, a person skilled in the art would understand that NSs 1800 can have a size distribution.

In some embodiments, NSs 1800 can include a homogenous population of NSs having sizes that emit in the blue visible wavelength spectrum, in the green visible wavelength spectrum, or in the red visible wavelength spectrum. In other embodiments, NSs 1800 can include a first population of NSs having sizes that emit in the blue visible wavelength spectrum, a second population of NSs having sizes that emit in the green visible wavelength spectrum, and a third population of NSs that emit in the red visible wavelength spectrum.

Matrix material 1910 can be any suitable host matrix material capable of housing NSs 1800. Suitable matrix materials can be chemically and optically compatible with NSs 1800 and any surrounding packaging materials or layers used in applying NS film 1900 to devices. Suitable matrix materials can include non-yellowing optical materials which are transparent to both the primary and secondary light, thereby allowing for both primary and secondary light to transmit through the matrix material. In some embodiments, matrix material 1910 can completely surround each of the NSs 1800. The matrix material 1910 can be flexible in applications where a flexible or moldable NS film 1900 is desired. Alternatively, matrix material 1910 can include a high-strength, non-flexible material.

Matrix material 1910 can include polymers and organic and inorganic oxides. Suitable polymers for use in matrix material 1910 can be any polymer known to the ordinarily skilled artisan that can be used for such a purpose. The polymer can be substantially translucent or substantially transparent. Matrix material 1910 can include, but not limited to, epoxies, acrylates, norbornene, polyethylene, poly(vinyl butyral): poly(vinyl acetate), polyurea, polyurethanes; silicones and silicone derivatives including, but not limited to, amino silicone (AMS), polyphenylmethylsiloxane, polyphenylalkylsiloxane, polydiphenylsiloxane, polydialkylsiloxane, silsesquioxanes, fluorinated silicones, and vinyl and hydride substituted silicones; acrylic polymers and copolymers formed from monomers including, but not limited to, methylmethacrylate, butylmethacrylate, and laurylmethacrylate; styrene-based polymers such as polystyrene, amino polystyrene (APS), and poly(acrylonitrile ethylene styrene) (AES); polymers that are crosslinked with bifunctional monomers, such as divinylbenzene; cross-linkers suitable for cross-linking ligand materials, epoxides which combine with ligand amines (e.g., APS or PEI ligand amines) to form epoxy, and the like.

In some embodiments, matrix material 1910 includes scattering particles such as TiO₂ microbeads, ZnS microbeads, or glass microbeads that can improve photo conversion efficiency of NS film 1900.

In another embodiment, matrix material 1910 can have low oxygen and moisture permeability, exhibit high photo- and chemical-stability, exhibit favorable refractive indices, and adhere to outer surfaces of NSs 1800, thus providing an air-tight seal to protect NSs 1800. In another embodiment, matrix material 1910 can be curable with UV or thermal curing methods to facilitate roll-to-roll processing.

According to some embodiments, NS film 1900 can be formed by mixing NSs 1800 in a polymer (e.g., photoresist) and casting the NS-polymer mixture on a substrate, mixing NSs 1800 with monomers and polymerizing them together, mixing NSs 1800 in a sol-gel to form an oxide, or any other method known to those skilled in the art.

According to some embodiments, the formation of NS film 1900 can include a film extrusion process. The film extrusion process can include forming a homogenous mixture of matrix material 1910 and barrier layer coated core-shell NSs such as NS 1800, introducing the homogenous mixture into a top mounted hopper that feeds into an extruder. In some embodiments, the homogenous mixture can be in the form of pellets. The film extrusion process can further include extruding NS film 1900 from a slot die and passing extruded NS film 1900 through chill rolls. In some embodiments, the extruded NS film 1900 can have a thickness less than about 75 μm, for example, in a range from about 70 μm to about 40 μm, from about 65 μm to about 40 μm, from about 60 μm to about 40 μm, or form about 50 μm to about 40 μm. In some embodiments, NS film 1900 has a thickness less than 10 μm. In some embodiments, the formation of NS film 1900 can optionally include a secondary process followed by the film extrusion process. The secondary process can include a process such as co-extrusion, thermoforming, vacuum forming, plasma treatment, molding, and/or embossing to provide a texture to a top surface of NS film 1900. The textured top surface NS film 1900 can help to improve, for example defined optical diffusion property and/or defined angular optical emission property of NS film 1900.

### Example Embodiments of Luminescent Nanostructures

Described herein are various compositions having luminescent nanostructures (NSs). The various properties of the luminescent nanostructures, including their absorption properties, emission properties and refractive index properties, can be tailored and adjusted for various applications.

The material properties of NSs can be substantially homogenous, or in certain embodiments, can be heterogeneous. The optical properties of NSs can be determined by their particle size, chemical or surface composition. The ability to tailor the luminescent NS size in the range between about 1 nm and about 15 nm can enable photoemission coverage in the entire optical spectrum to offer great versatility in color rendering. Particle encapsulation can offer robustness against chemical and UV deteriorating agents.

Luminescent NSs, for use in embodiments described herein can be produced using any method known to those skilled in the art. Suitable methods and example nanocrystals are disclosed in U.S. Pat. No. 7,374,807; U.S. patent application Ser. No. 10/796,832, filed Mar. 10, 2004; U.S. Pat. No. 6,949,206; and U.S. Provisional Patent Application No. 60/578,236, filed Jun. 8, 2004, the disclosures of each of which are incorporated by reference herein in their entireties.

Luminescent NSs for use in embodiments described herein can be produced from any suitable material, including an inorganic material, and more suitably an inorganic conductive or semiconductive material. Suitable semiconductor materials can include those disclosed in U.S. patent application Ser. No. 10/796,832, and can include any type of semiconductor, including group II-VI, group III-V, group IV-VI and group IV semiconductors. Suitable semiconductor materials can include, but are not limited to, Si, Ge, Sn, Se, Te, B, C (including diamond), P, BN, BP, BAS, AlN, AIP, AlAs, AlSb, GaN, GaP, GaAs, GaSb, InN, InP, InAs, InSb, AlN, AIP, AIAs, AlSb, GaN, GaP, GaAs, GaSb, ZnO, ZnS, ZnSe, ZnTe, CdS, CdSe, CdTe, HgS, HgSe, HgTe, Bes, BeSe, BeTe, MgS, MgSe, GeS, GeSe, GeTe, SuS, SnSe, SnTe, PbO, PbS, PbSe, PbTe, CuF, CuCl, CuBr, Cul, Si₃N₄, Ge₃N₄, Al₂O₃, (Al, Ga, In)₂ (S, Se, Te)₃, Al₂CO, and an appropriate combination of two or more such semiconductors.

In certain embodiments, the luminescent NSs can have a dopant from the group consisting of a p-type dopant or an n-type dopant. The NSs can also have II-VI or III-V semiconductors. Examples of II-VI or III-V semiconductor NSs can include any combination of an element from Group II, such as Zn, Cd and Hg, with any element from Group VI, such as S, Se, Te and Po, of the Periodic Table; and any combination of an element from Group III, such as B, Al, Ga, In, and Tl, with any element from Group V, such as N, P, As, Sb and Bi, of the Periodic Table.

The luminescent NSs, described herein can also further include ligands conjugated, cooperated, associated or attached to their surface. Suitable ligands can include any group known to those skilled in the art, including those disclosed in U.S. Pat. No. 8,283,412; U.S. Patent Publication No. 2008/0237540; U.S. Patent Publication No. 2010/0110728; U.S. Pat. Nos. 8,563,133; 7,645,397; 7,374,807; 6,949,206; 7,572,393; and 7,267,875, the disclosures of each of which are incorporated herein by reference. Use of such ligands can enhance the ability of the luminescent NSs to incorporate into various solvents and matrixes, including polymers. Increasing the miscibility (i.e., the ability to be mixed without separation) of the luminescent NSs in various solvents and matrixes can allow them to be distributed throughout a polymeric composition such that the NSs do not aggregate together and therefore do not scatter light. Such ligands are described as “miscibility-enhancing” ligands herein.

In certain embodiments, compositions having luminescent NSs distributed or embedded in a matrix material are provided. Suitable matrix materials can be any material known to the ordinarily skilled artisan, including polymeric materials, organic and inorganic oxides. Compositions described herein can be layers, encapsulants, coatings, sheets or films. It should be understood that in embodiments described herein where reference is made to a layer, polymeric layer, matrix, sheet or film, these terms are used interchangeably, and the embodiment so described is not limited to any one type of composition, but encompasses any matrix material or layer described herein or known in the art.

Down-converting NSs (for example, as disclosed in U.S. Pat. No. 7,374,807) utilize the emission properties of luminescent nanostructures that are tailored to absorb light of a particular wavelength and then emit at a second wavelength, thereby providing enhanced performance and efficiency of active sources (e.g., LEDs).

While any method known to the ordinarily skilled artisan can be used to create luminescent NSs, a solution-phase colloidal method for controlled growth of inorganic nanomaterial phosphors can be used. See Alivisatos, A. P., “Semiconductor clusters, nanocrystals, and quantum dots,” Science 271:933 (1996); X. Peng, M. Schlamp, A. Kadavanich, A. P. Alivisatos, “Epitaxial growth of highly luminescent CdSe/CdS Core/Shell nanocrystals with photostability and electronic accessibility,” J. Am. Chem. Soc. 30:7019-7029 (1997); and C. B. Murray, D. J. Norris, M. G. Bawendi, “Synthesis and characterization of nearly monodisperse CdE (E=sulfur, selenium, tellurium) semiconductor nanocrystallites,” J Am. Chem. Soc. 115:8706 (1993), the disclosures of which are incorporated by reference herein in their entireties.

According to some embodiments, CdSe can be used as the NS material, in one example, for visible light down-conversion, due to the relative maturity of the synthesis of this material. Due to the use of a generic surface chemistry, it can also possible to substitute non-cadmium-containing NSs.

In semiconductor NSs, photo-induced emission arises from the band edge states of the NS. The band-edge emission from luminescent NSs competes with radiative and non-radiative decay channels originating from surface electronic states. X. Peng, et al., J Am. Chem. Soc. 30:7019-7029 (1997). As a result, the presence of surface defects such as dangling bonds provide non-radiative recombination centers and contribute to lowered emission efficiency. An efficient and permanent method to passivate and remove the surface trap states can be to epitaxially grow an inorganic shell material on the surface of the NS. X. Peng, et al., J. Am. Chem. Soc. 30:7019-7029 (1997). The shell material can be chosen such that the electronic levels are type 1 with respect to the core material (e.g., with a larger bandgap to provide a potential step localizing the electron and hole to the core). As a result, the probability of non-radiative recombination can be reduced.

Core-shell structures can be obtained by adding organometallic precursors containing the shell materials to a reaction mixture containing the core NSs. In this case, rather than a nucleation event followed by growth, the cores act as the nuclei, and the shells can grow from their surface. The temperature of the reaction is kept low to favor the addition of shell material monomers to the core surface, while preventing independent nucleation of nanocrystals of the shell materials. Surfactants in the reaction mixture are present to direct the controlled growth of shell material and to ensure solubility. A uniform and epitaxially grown shell can be obtained when there is a low lattice mismatch between the two materials.

Example materials for preparing core-shell luminescent NSs can include, but are not limited to, Si, Ge, Sn, Se, Te, B, C (including diamond), P, Co, Au, BN, BP, BAS, AlN, AIP, AlAs, AlSb, GaN, GaP, GaAs, GaSb, InN, InP, InAs, InSb, AlN, AIP, AlAs, AlSb, GaN, GaP, GaAs, GaSb, ZnO, ZnS, ZnSe, ZnTe, CdS, CdSe, CdTe, HgS, HgSe, HgTc, BeS, BcSe, BcTe, MgS, MgSe, GeS, GeSe, GeTe, SnS, SnSe, SnTe, PbO, PbS, PbSe, PbTe, CuP, CuCl, CuBr, Cul, Si₃N₄, Ge₃N₄, Al₂O₃, (Al, Ga, In)₂ (S, Se, Te)₃, AlCO, and shell luminescent NSs for use in the practice of the present invention include, but are not limited to, (represented as Core/Shell), CdSe/ZnS, InP/ZnS, InP/ZnSe, PbSe/PbS, CdSe/CdS, CdTe/CdS, CdTe/ZnS, as well as others.

Luminescent NSs for use in the embodiments described herein can be less than about 100 nm in size, and down to less than about 2 nm in size and invention absorb visible light. As used herein, visible light is electromagnetic radiation with wavelengths between about 380 and about 780 nanometers that is visible to the human eye. Visible light can be separated into the various colors of the spectrum, such as red, orange, yellow, green, blue, indigo and violet. Blue light can comprise light between about 435 nm and about 495 nm, green light can comprise light between about 495 nm and 570 nm and red light can comprise light between about 620 nm and about 750 nm in wavelength.

According to various embodiments, the luminescent NSs can have a size and a composition such that they absorb photons that are in the ultraviolet, near-infrared, and/or infrared spectra. The ultraviolet spectrum can comprise light between about 100 nm to about 400 nm, the near-infrared spectrum can comprise light between about 750 nm to about 100 μm in wavelength, and the infrared spectrum can comprise light between about 750 nm to about 300 μm in wavelength.

While luminescent NSs of other suitable material can be used in the various embodiments described herein, in certain embodiments, the NSs can be ZnS, InAs, CdSe, or any combination thereof to form a population of nanocrystals for use in the embodiments described herein. As discussed above, in further embodiments, the luminescent NSs can be core/shell nanocrystals, such as CdSe/ZnS, InP/ZnSe, CdSe/CdS or InP/ZnS.

Suitable luminescent nanostructures, methods of preparing luminescent nanostructures, including the addition of various solubility-enhancing ligands, can be found in Published U.S. Patent Publication No. 2012/0113672, the disclosure of which is incorporated by reference herein in its entirety.

It is to be understood that while certain embodiments have been illustrated and described herein, the claims are not to be limited to the specific forms or arrangement of parts described and shown. In the specification, there have been disclosed illustrative embodiments and, although specific terms are employed, they are used in a generic and descriptive sense only and not for purposes of limitation. Modifications and variations of the embodiments are possible in light of the above teachings. It is therefore to be understood that the embodiments can be practiced otherwise than as specifically described.

The invention claimed is:

1. A display device comprising:
a substrate; and
a sub-pixel configured to emit a display light having an emission spectrum comprising a first peak wavelength and a second peak wavelength, wherein the sub-pixel comprises:
a nanostructure-based color conversion (NS-based CC) layer comprising quantum dots (QDs) configured to emit a first light having the first peak wavelength; and
a microLED disposed on the substrate configured to emit a second light having the second peak wavelength,
wherein the NS-based CC layer is disposed on the microLED,
wherein a first portion of the second light is absorbed by the QDs and down-converted to the first light, and
wherein a second portion of the second light is transmitted through the NS-based CC layer.

2. The display device of claim 1, wherein the first peak wavelength is in a wavelength range of about 620 nm to about 750 nm.

3. The display device of claim 1, wherein the second peak wavelength is in a wavelength range of about 550 nm to about 610 nm.

4. The display device of claim 1, wherein the first and second peak wavelengths are in different and adjacent wavelength regions of an electromagnetic (EM) spectrum.

5. (canceled)

6. The display device of claim 1, wherein an intensity of the first peak wavelength is greater than an intensity of the second peak wavelength.

7-10. (canceled)

11. The display device of claim 1, wherein an optical transmission of the microLED ranging from about 100% to about 1% at the second peak wavelength corresponds to an optical density of the NS-based CC layer ranging from about 0 to about 3.0.

12. (canceled)

13. The display device of claim 1, wherein the microLED has an optical transmission of about 1% to about 70% at the second peak wavelength through the NS-based CC layer.

14. The display device of claim 1, wherein the NS-based CC layer comprises a surface area of about 0.5 pm×about 0.5 μm to about 1000 pm×about 1000 pm.

15-16. (canceled)

17. The display device of claim 1, wherein the NS-based CC layer comprises a thickness of about 5 μm to about 40 pm.

18. The display device of claim 1, wherein the NS-based CC layer comprises an optical density of about 0.1 to about 3.0.

19-20. (canceled)

21. A display device comprising:
a substrate;
a first sub-pixel configured to emit a first display light having a first emission spectrum comprising a first peak wavelength and a second peak wavelength, wherein the first sub-pixel comprises:
a first nanostructure-based color conversion (NS-based CC) layer comprising a first set of quantum dots (QDs) configured to emit a first light having the first peak wavelength, and
a first microLED disposed on the substrate configured to emit a second light having the second peak wavelength, wherein the NS-based CC layer is disposed on the first microLED; and
a second sub-pixel is configured to emit a second display light having a second emission spectrum comprising a third peak wavelength and a fourth peak wavelength,
wherein the third and fourth peak wavelengths are different from the first and second peak wavelengths, respectively, and
wherein the second sub-pixel comprises:
a second NS-based CC layer comprising a second set of quantum dots (QDs) configured to emit a third light having the third peak wavelength, and
a second microLED disposed on the substrate configured to emit a fourth light having the fourth peak wavelength, wherein the second NS-based CC layer is disposed on the second microLED.

22. The display device of claim 21, wherein the first emission spectrum corresponds to a first color point having a first chromaticity (x, y) coordinates on an RGB color space, and wherein the second emission spectrum corresponds to a second color point having a second chromaticity (x, y) coordinates on the RGB color space, the second chromaticity (x, y) coordinates being different from the first chromaticity (x, y) coordinates.

23. The display device of claim 21, wherein the first and third peak wavelengths are in a wavelength range of about 620 nm to about 750 nm.

24. The display device of claim 21, wherein the second and fourth peak wavelengths are in a wavelength range of about 550 nm to about 610 nm.

25-30. (canceled)

31. A method of fabricating a display device, comprising:
forming first and second microLEDs on a substrate, wherein the first microLED is formed to emit a first display light having a first emission spectrum comprising a dual peak wavelength and the second microLED is formed to emit a second display light having a second emission spectrum comprising a single peak wavelength;
depositing a layer of quantum dots (QDs) on the first and second microLEDs; masking a first portion of the layer of QDs;
performing a hardening process on a second portion of the layer of QDs; and
removing the first portion of the layer of QDs.

32-40. (canceled)
